(19) United States
(12) Patent Application Publication
(10) Pub. No.: US 2025/0360822 A1
(43) Pub. Date: Nov. 27, 2025

(54) VEHICLE CHARGING DEVICE WITH OPTIMIZED COOLING

(71) Applicant: BRUSA ELEKTRONIK AG, Buchs (CH)

(72) Inventors: Nikola IVANCIC, Buchs (CH); Ueli WENDELSPIESS, Buchs (CH); Sebastian WÜSTNER, Buchs (CH); Bernardo TORREJANO, Buchs (CH); Lukas BÖHLER, Buchs (CH); Veit PFÄTTISCH, Buchs (CH); Simon ISLINGER, Buchs (CH)

(21) Appl. No.: 19/108,358

(22) PCT Filed: Aug. 30, 2023
(86) PCT No.: PCT/EP2023/073775

§ 371 Date: Mar. 3, 2025

(30) Foreign Application Priority Data
Sep. 8, 2022 (DE) 10 2022 122 861.4

(51) Int. Cl. B60L 53/302; B60L 53/12; H05K 7/20

(52) U.S. Cl. CPC B60L 53/302; B60L 53/12; H05K 7/20145; H05K 7/20172; H05K 7/20209; H05K 7/20272; H05K 7/20281; H05K 7/20909; H05K 7/20927; H05K 7/20945; B60L 2210/40

(57) ABSTRACT

A vehicle charging device for inductively charging an energy accumulator of a vehicle, the vehicle charging device comprising an interface for receiving electric power, a first section comprising at least a coil, a second section comprising power electronics configured to convert the electric power received with the interface to a defined AC current, and a cooling system comprising a fluid accelerator, a fluid inlet, and a fluid outlet, the cooling system configured for cooling the vehicle charging device with a fluid, wherein the first section and the second section are spatially separated, wherein the cooling system includes a first cooling path in the first section and a second cooling path in the second section, the fluid inlet in the first section and the fluid outlet in the second section, and wherein the fluid accelerator is configured for transporting the fluid from the first cooling path to the second cooling path.

### CROSS-REFERENCE TO RELATED APPLICATIONS

The present application is the U.S. National Phase of PCT/EP2023/073775, filed on 30 Aug. 2023, which claims priority to German Patent Application No. DE 10 2022 122 861.4, filed on 8 Sep. 2022, the entire contents of which are incorporated herein by reference.

### FIELD OF THE INVENTION

The present invention relates to a vehicle charging device for inductively charging an energy accumulator of a vehicle.

### BACKGROUND OF THE INVENTION

Wirelessly charging electric vehicles provides many benefits. For example, charging may be performed automatically with no driver intervention and manipulations and thus provides a seamless user experience.

Also, reliability of the wireless power transfer system is ensured because there are no exposed electrical contacts and no mechanical wear out. Manipulations with cables and connectors are not needed, and there may be no cables, plugs, or sockets that may be accessible or exposed to moisture and water in an outdoor environment, thereby improving safety and prevent vandalism.

Inductive power transfer systems that are designed to transfer up to 11 kW of power require an active cooling both for the charging device and the vehicle-side power receiving unit. This is particularly crucial when the vehicle charging device is embodied in one compact housing where the power electronics assembly is incorporated as well as the magnetics assembly. The combined package must be flat so that vehicles can move over it.

Commonly, about 500 W of power need to be dissipated at a 90% efficiency and a distribution of 50% between charger-side and vehicle-side. Depending on the specific implementation, this power is distributed nearly equally between the magnetics and the power electronics compartments of the vehicle charging device.

One technical problem in this technical field is to efficiently cool these multiple components within the magnetics and power electronics compartments inside the flat charging device housing, where the components have very different cooling requirements. Some components have distributed power density, while the heating is very localized in others.

Some components can stand high temperatures, while others require comparably low temperatures. Some components have potentially large cooling interfaces, others do not. Some components need additional high voltage protection that can be detrimental to an implementation of efficient cooling interfaces. Some components need protection from environmental impact, while others can be exposed to the environment, e.g., air used as fluid for cooling.

### OBJECT OF THE INVENTION

The invention therefore provides an improved vehicle charging device. The invention particularly provides an improved cooling system for a vehicle charging device. A vehicle charging device according to the invention allows for a safer, more efficient, and faster vehicle charging process.

### SUMMARY OF THE INVENTION

The invention relates to a vehicle charging device for inductively charging an energy accumulator of a vehicle, the vehicle charging device comprising an interface for receiving electric power, a first section comprising at least a coil, a second section comprising power electronics configured to convert the electric power received with the interface to a defined AC current, and a cooling system comprising a fluid accelerator, a fluid inlet, and a fluid outlet, the cooling system configured for cooling the vehicle charging device with a fluid, wherein the first section and the second section are spatially separated, wherein the cooling system comprises a first cooling path arranged in the first section and a second cooling path arranged in the second section, wherein the fluid inlet is arranged in the first section and the fluid outlet is arranged in the second section, and wherein the fluid accelerator is configured for transporting the fluid from the first cooling path to the second cooling path.

In some embodiments, the second cooling path comprises a cooling geometry configured to provide heat dissipation from the power electronics to the fluid, in particular, wherein the cooling geometry is formed by at least one fin.

In some embodiments, the at least one fin consists at least in part of a thermally conductive material.

In some embodiments, the at least one fin forks at least part of the second cooling path into two or more separate channels.

In some embodiments, a total cross sectional area of the fluid inlet is larger than a total cross sectional area of the fluid outlet.

In some embodiments, the first section further comprises a magnetizable element.

The vehicle charging device according to any of the preceding embodiments, wherein the coil is a printed circuit board (PCB) coil.

In some embodiments, the fluid accelerator comprises blades.

In some embodiments, the fluid accelerator comprises an impeller, a turbine, or a fan.

In some embodiments, the first cooling path comprises a first layer and a second layer, and wherein the magnetizable element and the coil are placed between the first and second layers.

In some embodiments, the magnetizable element is separated from the coil by a thermally and electrically insulating substrate.

In some embodiments, the second section comprises a first region and a second region.

In some embodiments, the first region comprises a first type cooling geometry and the second region comprises a second type cooling geometry differing from the first type cooling geometry, and wherein the first region comprises first type power electronics and the second region comprises second type power electronics, wherein the first type cooling geometry is dimensioned and/or shaped according to a heat emission of the first type power electronics and the second type cooling geometry is dimensioned and/or shaped according to a heat emission of the second type power electronics.

In some embodiments, the first type power electronics is a power factor correction (PFC) and the second type power electronics is an inverter.

In some embodiments, the vehicle charging device further comprises at least one temperature sensor and a control unit configured to regulate the fluid accelerator based on temperature data obtained with the at least one temperature sensor.

In some embodiments, the vehicle charging device further comprises a housing, wherein the fluid accelerator is fully integrated in the housing.

In some embodiments, at least a portion of the fluid inlet and at least a portion of the fluid outlet are arranged on opposite sides of the housing of the vehicle charging device.

In some embodiments, the vehicle charging device further comprises a communication unit and a control unit configured to regulate the fluid accelerator based on command data obtained with the communication unit.

In some embodiments, the fluid is air, wherein the vehicle charging device comprises an exhaust air unit configured to transport the air from the fluid outlet into an environment isolated from a location of the vehicle charging device.

In some embodiments, the fluid may be a coolant (e.g., oil or water), wherein the cooling system further comprises a coolant circulation system with heat sink.

### BRIEF DESCRIPTION OF THE DRAWINGS

By way of example only, preferred embodiments of the invention will be described more fully hereinafter with reference to the accompanying figures, wherein:

FIGS. 1 and 2 show the charging initiation process of a vehicle 1 with an energy accumulator;

FIGS. 3 and 4 are abstracted illustrations of two example embodiments of the inventive vehicle charging device in a horizontal side view;

FIG. 5 shows an example layout of the part comprising the at least one magnetizable element and the at least one coil; and

FIG. 6 is a sectional view as defined in FIG. 3 with the dashdotted line.

### DETAILED DESCRIPTION OF THE DRAWINGS

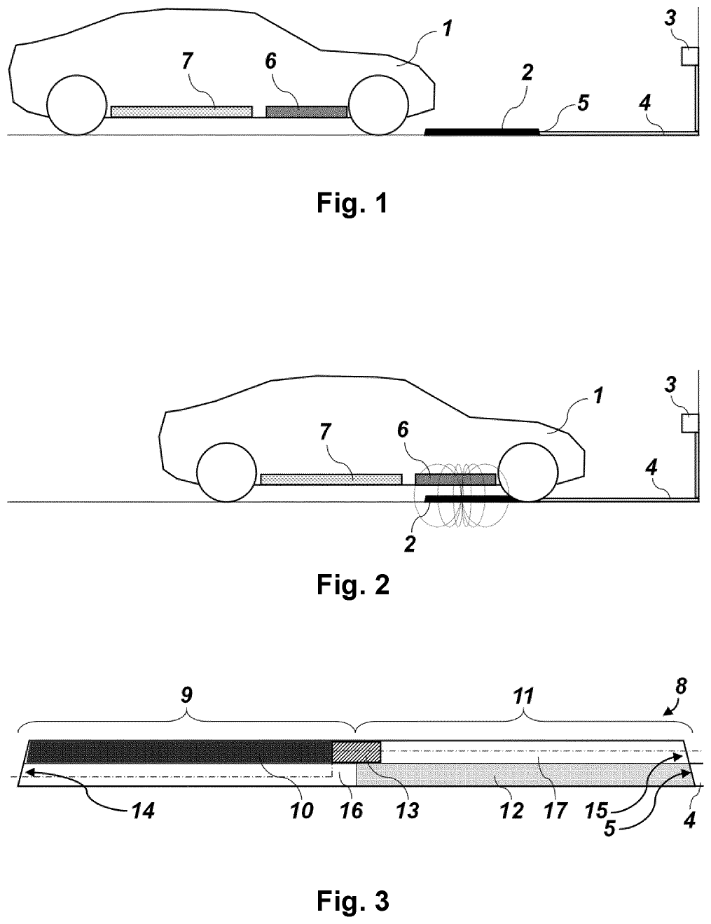

FIGS. 1 and 2 show the charging initiation process of a vehicle 1 with an energy accumulator, e.g., an electric vehicle or a hybrid-electric vehicle. The vehicle 1 moves over the vehicle charging device 2, which is connected to a power outlet 3 by the cable 4 via the interface 5. The charging process begins upon manual activation or automatic detection of the vehicle 1. The vehicle 1 has an inductive charging receiver 6 which is to be positioned above the vehicle charging device 2. The inductive charging receiver 6 is configured to charge an energy accumulator 7 of the vehicle 1.

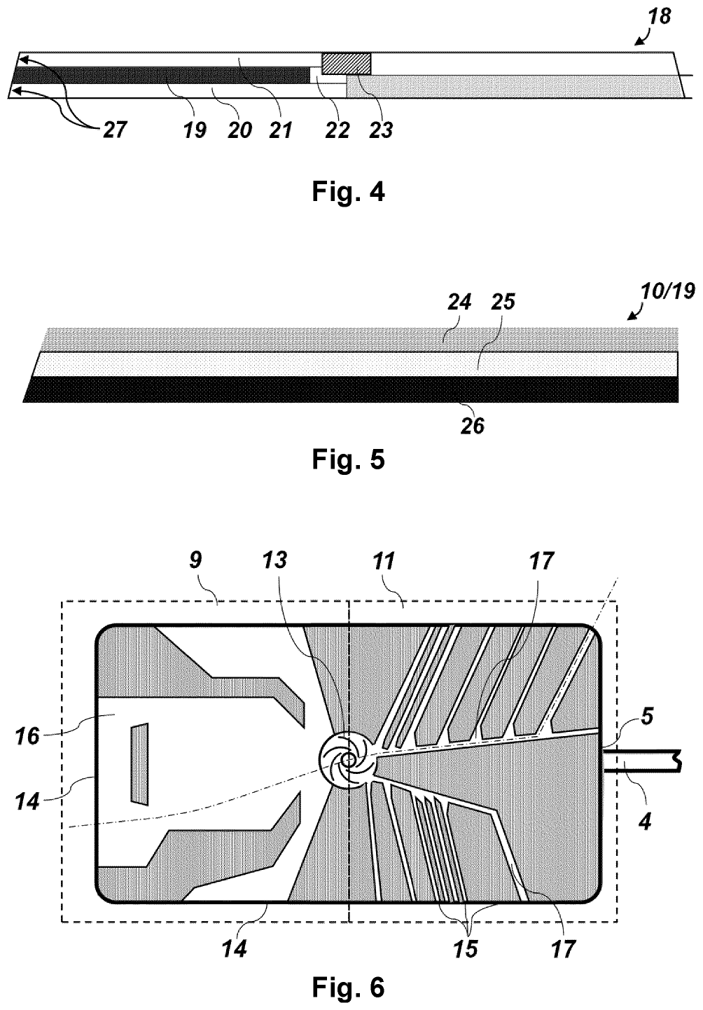

FIGS. 3 and 4 show two example embodiments of the inventive vehicle charging device in a horizontal side view. Referring first to FIG. 3, the vehicle charging device 8 comprises (a) a first section 9 comprising a compartment 10 with a coil, in particular a litz wire coil, and (b) a second section 11 comprising power electronics 12 configured to convert the electric power received from the power outlet 3 to a defined AC current, in particular to a low-frequency AC current. In the embodiments shown herein, the compartment 10 advantageously also comprises a magnetizable element, in particular a ferrite element.

The vehicle charging device 8 further comprises a cooling system comprising a fluid accelerator 13, a fluid inlet 14, and a fluid outlet 15, the cooling system configured for cooling the vehicle charging device with a fluid, which is in this example air from the environment. Generally, the fluid inlet and/or the fluid outlet may comprise a screen for preventing particles or insects to enter the cooling system.

Still referring to FIG. 3, the first section 9 and the second section 11 of the vehicle charging device 8 are spatially separated, wherein a first cooling path 16 of the cooling system is arranged in the first section 9 and a second cooling path 17 of the cooling system is arranged in the second section 11. In this example, the first cooling path 16 is located in a lower part of the vehicle charging device 8, and the second cooling path 17 is located in an upper part of the vehicle charging device 8. However, the cooling paths can be arranged in any vertical sequence or position within the respective sections. In particular, the first cooling path may in other embodiments also be arranged in the lower part of the vehicle charging device.

The fluid inlet 14 is arranged in the first section 9 and the fluid outlet 15 is arranged in the second section 11. The fluid accelerator 13 is configured for transporting the fluid from the first cooling path 16 to the second cooling path 17, in particular wherein the fluid accelerator 13 is positioned at the border between the first section 9 and the second section 11. Specifically, the accelerator 13 is integrated in a housing of the charging device so that it can only attract fluid from the first cooling path and only discharge the fluid into the second cooling path. The accelerator being integrated inside the housing lowers its noise level.

In particular, the second cooling path 17 differs from the first cooling path 16 by at least one of the following aspects: (a) a total cross sectional area of the fluid inlet is larger than a total cross sectional area of the fluid outlet; (b) the second cooling path has less volume than the first cooling path, the fluid has a higher average speed through the second cooling path; (c) a total inside surface of the second cooling path is higher than a total inside surface of the first cooling path.

FIG. 4 shows an alternative embodiment 18 of a vehicle charging device, wherein the part 19 with one or more magnetizable elements and one or more coils is positioned as an intermediate layer between a first layer 20 and a second layer 21 comprised by the first cooling path. The fluid accesses the first cooling path 20 via the inlets 27. A recess 22 allows the air or fluid from the second layer 21 to reach the bottom of the fluid accelerator 23, which is here embodied as an impeller that sucks in air from below and passes it on radially outwards. With regard to the division of the first and second section and the design of the second section it is referred to the embodiment of FIG. 3. Other fluid accelerators are of course also applicable, such as a fan.

FIG. 5 shows an example layout of the part comprising the at least one magnetizable element and the at least one coil, of which embodiments are shown in FIGS. 3 and 4 (see reference 10 or 19). The coil unit 24 is arranged on the upper side to have minimal distance to the inductive charging receiver 6 of the car 1. The unit 24 is divided from the magnetizable element 26 by a layer 25 made of a material, e.g., plastic, that is both electrically isolating, in particular, also thermally isolating.

In case the layer 25 also provides thermal isolation, the heat emission from the coil 24 and the heat emission from the magnetizable element 26 are separated so that the respective heat can be dissipated by the air flowing through the first layer 21 of the first cooling path and, respectively, by the air flowing through the second layer 20 of the first cooling path. However, the layout presented in FIG. 5 is also applicable to the charger 8 in FIG. 3 or to the variant having the coil compartment in the bottom of the housing.

The magnetics components (coil compartment) comprised in the first section and the electronics components comprised in the second section both have a substantially different distribution of heat emission. In the first section, the heat evolves relatively evenly throughout the first cooling path, whereas in the second section, the heat evolves locally concentrated adjacent to the electronic components. These electronic components may comprise an inverter, in particular, also a power factor correction (PFC). Due to the high voltage, the generated heat is quite significant and an effective cooling is thus necessary for the vehicle charging device to work without disturbance and outage.

The division of the differently characterized parts to be cooled by different cooling paths allows for an effective cooling, wherein only one fluid accelerator is required. The use of only one accelerator is advantageous because of their relatively large dimensions caused by the amount of heat to be dissipated. However, of course, according to the invention the vehicle charging device can have more than just one fluid accelerator. The increased efficacy allows for a compact one-box construction of the vehicle charging device. The fact that all major components can be housed by the vehicle charging device increases the overall charging safety and electromagnetic compatibility as there is no high-voltage cable necessary that would lead to the charging device.

As mentioned before, a further advantage of embodiments is the low sound emission because the vehicle charging device allows the fan(s) (fluid accelerator(s)) to be arranged in the inside so that the sound is encapsulated by the housing of the vehicle charging device.

FIG. 6 is a sectional view as defined in FIG. 3 with the dashdotted line. In turn, FIG. 3 is a sectional view of the dashdotted line as drawn in FIG. 6. As can be seen in FIG. 6, the first cooling path 16 in the first section 9 has less internal cooling surface compared to the second cooling path 17 in the second section 11. Further, in the shown example, the fluid travels slower (at least on average) and more evenly in the first path 16 as its volume is larger than that of the second path 17. The faster and more winding flow in the second path 17 may in particular cause turbulences which improve the cooling performance. In the second cooling path 17, on average, the fluid travels faster due to the special design of the cooling geometry along the second path 17.

The impeller 13 attracts the pre-heated air from the first cooling path 16 and transports it into the second cooling path 17 by releasing it there radially. Even if the initial temperature of the air in the second cooling path 17 is higher than that of the first cooling path 16, the fluid in second path 17 can still effectively cool the components due to the larger cooling surface.

In the shown embodiment, the second section 11 comprises elongated islands (or in other words: fins) along which the thin channels of the second cooling path 17 proceed. The fins divide the paths of the fluid and can, depending on their shape, increase turbulences. The islands or fins increase the surface that the fluid is in contact with and therefore improves heat dissipation. A further improvement could be introduced when the fins are made of a material that has a high thermal conductivity, such as aluminium.

These ways of splitting up from a wider channel into many thin channels may be labelled forking. The second cooling path 17 thus comprises in a preferred embodiment a first main fork and a second main fork, wherein the second section 11 comprises these forks respectively in a first region (in FIG. 6 the fork above the dash-dotted line) and in a second region (in FIG. 6 the fork below the dash-dotted line).

The first region may comprise first type power electronics and the second region may comprise second type power electronics, wherein the first main fork is dimensioned and/or shaped (first type cooling geometry) according to heat emission characteristics of the first type power electronics and the second main fork is dimensioned and/or shaped (second type cooling geometry) according to heat emission characteristics of the second type power electronics. This way, the forks can be specifically adapted to dissipate the heat exactly as it emerges from the two main components. These two differently typed power electronics are based in the compartment 12, i.e., underneath (or in other embodiments: above) the second cooling path 17. Specifically, these two components may comprise but are not limited to the inverter and/or the power factor correction (PFC).

In some embodiments (not shown), the fluid inlet and the fluid outlet are strictly separated to be arranged on opposing sides of the housing of the vehicle charging device in order to make sure that the air dissipating the heat out of the fluid outlet is not in part being immediately sucked in again by the fluid inlet.

In further embodiments, the vehicle charging device may comprise an exhaust air unit configured to transport the air from the fluid outlet into an environment isolated from a location of the vehicle charging device, i.e., for example, into a neighboring room or to the outside (e.g., if the vehicle charging device is located in a garage). Such an exhaust air unit may comprise a suction device and/or suction hose.

Further embodiments provide at least one temperature sensor based on which the vehicle charging device may be controlled by a control unit. The control unit would then regulate the fluid accelerator (i.e., its rotational speed and/or its activation and deactivation) depending on temperature data obtained with the temperature sensor. Alternatively or additionally, the charging speed/performance could be controlled based on measured temperature(s).

For example, there might be a specific temperature of the vehicle charging device (or individual components thereof) under which it works best, wherein the specific temperature differs from the ambient temperature. The control unit might then activate/deactivate/regulate the fluid accelerator such that the specific temperature is reached and maintained.

Example positions of such a temperature sensor are at the fluid inlet; in the first path before entering the fluid accelerator; in the fluid accelerator; at the exit of the fluid accelerator; at the fluid outlet; adjacent to a specific component of the charger (e.g., coils, magnetizable element, inverter, PFC).

Some embodiments may comprise a communication unit that, for example, uses wired or wireless technology to receive commands from external devices, such as a smartphone or a computer comprised by the electric vehicle that is (to be) charged by the vehicle charging device. For example, in case a charging process is scheduled, the fluid accelerator could be activated/deactivated/regulated depending on the planned charging start or on the charging progress. Specifically, the vehicle charging device could be pre-cooled for a planned charging process and/or could be post-cooled for a defined time after the charging process finished, or until a desired temperature (monitored by optional temperature sensor(s)) is reached.

Although the invention is illustrated above, partly with reference to some preferred embodiments, it must be understood that numerous modifications and combinations of different features of the embodiments can be made. All of these modifications lie within the scope of the appended claims.

1. A vehicle charging device for inductively charging an energy accumulator of a vehicle, the vehicle charging device comprising:
an interface for receiving electric power;
a first section comprising at least a coil;
a second section comprising power electronics configured to convert the electric power received with the interface to a defined AC current, wherein the first section and the second section are spatially separated; and
a cooling system comprising a fluid accelerator, a fluid inlet, and a fluid outlet, the cooling system configured for cooling the vehicle charging device with a fluid, wherein the cooling system comprises:
a first cooling path arranged in the first section; and
a second cooling path arranged in the second section, wherein the fluid inlet is arranged in the first section and the fluid outlet is arranged in the second section, and the fluid accelerator is configured for transporting the fluid from the first cooling path to the second cooling path.

2. The vehicle charging device according to claim 1, wherein the second cooling path comprises a cooling geometry configured to provide heat dissipation from the power electronics to the fluid.

3. (canceled)

4. (canceled)

5. The vehicle charging device according to claim 1, wherein a total cross sectional area of the fluid inlet is larger than a total cross sectional area of the fluid outlet.

6. The vehicle charging device according to claim 1, wherein the first section further comprises a magnetizable element.

7. The vehicle charging device according to claim 1, wherein the coil is a printed circuit board (PCB) coil.

8. The vehicle charging device according to claim 1, wherein the fluid accelerator comprises blades.

9. The vehicle charging device according to claim 1, wherein the fluid accelerator comprises an impeller, a turbine, or a fan.

10. The vehicle charging device according to claim 1, wherein the first cooling path comprises a first layer and a second layer, and wherein a magnetizable element and the coil are placed between said first and second layers.

11. The vehicle charging device according to claim 10, wherein the magnetizable element is separated from the coil by a thermally and electrically insulating substrate.

12. The vehicle charging device according to claim 1, wherein the second section comprises a first region and a second region.

13. The vehicle charging device according to claim 12, wherein the first region comprises a first type cooling geometry and the second region comprises a second type cooling geometry differing from the first type cooling geometry, and wherein the first region comprises first type power electronics and the second region comprises second type power electronics, wherein the first type cooling geometry is dimensioned and/or shaped according to a heat emission of the first type power electronics and the second type cooling geometry is dimensioned and/or shaped according to a heat emission of the second type power electronics.

14. The vehicle charging device according to claim 13, wherein the first type power electronics is a power factor correction (PFC) and the second type power electronics is an inverter.

15. The vehicle charging device according to claim 1, comprising at least one temperature sensor and a control unit configured to regulate the fluid accelerator based on temperature data obtained with the at least one temperature sensor.

16. The vehicle charging device according to claim 2, wherein the cooling geometry is formed by at least one fin.

17. The vehicle charging device according to claim 16, wherein the at least one fin consists at least in part of a thermally conductive material.

18. The vehicle charging device according to claim 16, wherein the at least one fin forks at least part of the second cooling path into two or more separate channels.
